(19) United States
(12) Patent Application Publication
(10) Pub. No.: US 2026/0123421 A1
(43) Pub. Date: Apr. 30, 2026

(54) SEMICONDUCTOR PACKAGE

(71) Applicant: Samsung Electronics Co., Ltd., Suwon-si (KR)

(72) Inventors: Sohyun JI, Suwon-si (KR); Inhee YOO, Suwon-si (KR)

(73) Assignee: Samsung Electronics Co., Ltd., Suwon-si (KR)

(21) Appl. No.: 19/260,708

(22) Filed: Jul. 7, 2025

(30) Foreign Application Priority Data
Oct. 29, 2024 (KR) 10-2024-0149596

(51) Int. Cl. H01L 23/373; H01L 23/00; H01L 23/31

(52) U.S. Cl. CPC H10W 40/259; H10W 74/121; H10W 72/884; H10W 74/15; H10W 90/724; H10W 90/734; H10W 90/754

(57) ABSTRACT

A semiconductor package includes a package substrate, a semiconductor chip on an upper surface of the package substrate, the semiconductor chip having a first surface facing the package substrate and a second surface opposite to the first surface, the semiconductor chip having a first thermal expansion coefficient, a stress control layer on the second surface of the semiconductor chip, the stress control layer having a second thermal expansion coefficient greater than the first thermal expansion coefficient so as to have a residual stress in a compressive direction, and a sealing member on the upper surface of the package substrate and covering the semiconductor chip and the stress control layer.

### PRIORITY STATEMENT

This application claims priority under 35 U.S.C. § 119 to Korean Patent Application No. 10-2024-0149596, filed on Oct. 29, 2024 in the Korean Intellectual Property Office (KIPO), the contents of which are herein incorporated by reference in their entirety.

### BACKGROUND

### 1. Field

Example embodiments relate to package substrates, semiconductor packages and methods of manufacturing the semiconductor package. More particularly, example embodiments relate to semiconductor packages manufactured through a bending test and a method for manufacturing the same.

### 2. Description of the Related Art

In manufacturing a semiconductor package, after a semiconductor chip is mounted on a package substrate, a sealing member such as epoxy mold compound (EMC) may be formed to protect the semiconductor chip from an external environment such as heat and moisture. Then, a 3-point bending test may be performed to measure mechanical properties such as flexural modulus, flexural strength, and/or flexural yield strength of the semiconductor package. In the 3-point bending test, a load may be applied to the package substrate to induce bending. At this time, tensile stress may be generated in the semiconductor chip, which may cause cracks to occur in the semiconductor chip and/or the sealing member.

### SUMMARY

Some example embodiments provide semiconductor packages having improved mechanical reliability and/or capable of alleviating stress occurring in a bending test.

According to an example embodiment, a semiconductor package includes a package substrate, a semiconductor chip on an upper surface of the package substrate, the semiconductor chip having a first surface facing the package substrate and a second surface opposite to the first surface, the semiconductor chip having a first thermal expansion coefficient, a first stress control layer on the second surface of the semiconductor chip, the first stress control layer having a second thermal expansion coefficient greater than the first thermal expansion coefficient, and a sealing member on the upper surface of the package substrate and covering the semiconductor chip and the first stress control layer.

According to an example embodiment, a semiconductor package includes a package substrate, a semiconductor chip on an upper surface of the package substrate and having a first thermal expansion coefficient, a sealing member on an upper surface of the package substrate and covering the semiconductor chip, and a first stress control layer coated on an upper surface of the sealing member, the first stress control layer having a second thermal expansion coefficient greater than the first thermal expansion coefficient.

According to an example embodiment, a semiconductor package includes a package substrate, a semiconductor chip on an upper surface of the package substrate, the semiconductor chip having a first surface facing the package substrate and a second surface opposite to the first surface, the semiconductor chip having a first thermal expansion coefficient, a first stress control layer on the second surface of the semiconductor chip, the first stress control layer having a second thermal expansion coefficient greater than the first thermal expansion coefficient, a sealing member on an upper surface of the package substrate and covering the semiconductor chip and the first stress control layer, and a second stress control layer on an upper surface of the sealing member, the second stress control layer having a third thermal expansion coefficient greater than the first thermal expansion coefficient.

According to an example embodiment, a semiconductor package may a package substrate, a semiconductor chip on the package substrate, the semiconductor chip having a first thermal expansion coefficient, a stress control layer on an upper surface of the semiconductor chip, the stress control layer having a second thermal expansion coefficient greater than the first thermal expansion coefficient, and a sealing member on the package substrate and covering the semiconductor chip and the stress control layer.

According to an example embodiment, a method for manufacturing a semiconductor package includes mounting a semiconductor chip on a package substrate, the semiconductor chip having a first thermal expansion coefficient, forming a first stress control layer on the semiconductor chip, the first stress control layer having a second thermal expansion coefficient greater than the first thermal expansion coefficient, and forming a sealing member to cover the semiconductor chip and the first stress control layer on the package substrate.

The method may further include forming a second stress control layer on the sealing member, the second stress control layer having a third thermal expansion coefficient greater than the first thermal expansion coefficient.

After manufacturing the semiconductor package, a 3-point bending test may be performed on the semiconductor package to measure mechanical properties of the semiconductor package. In 3-point bending test, bending deformation (upward convexity) may occur in the semiconductor package. A tensile stress may occur in the semiconductor chip due to the bending deformation of the semiconductor package. Because the stress control layer has the residual stress in the compressive direction at room temperature, the stress control layer may relieve or alleviate the tensile stress applied to the semiconductor chip.

Accordingly, the strength of the semiconductor package in the bending test may be increased and cracks may be reduced or prevented from occurring in the sealing member on which a marking pattern is formed.

### BRIEF DESCRIPTION OF THE DRAWINGS

Example embodiments will be more clearly understood from the following detailed description taken in conjunction with the accompanying drawings. FIGS. 1 to 8 represent non-limiting example embodiments as described herein.

FIG. 1 is a cross-sectional view illustrating a semiconductor package in accordance with an example embodiment.

FIGS. 2 to 5 are views illustrating a method for manufacturing a semiconductor package in accordance with an example embodiment.

FIGS. 6A and 6B are views illustrating a bending of a semiconductor package in accordance with an example embodiment when a load is applied to the semiconductor package by an upper pressurizing member.

FIG. 7 is a cross-sectional view illustrating a semiconductor package in accordance with an example embodiment.

FIG. 8 is a cross-sectional view illustrating a semiconductor package in accordance with an example embodiment.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, some example embodiments will be explained in detail with reference to the accompanying drawings.

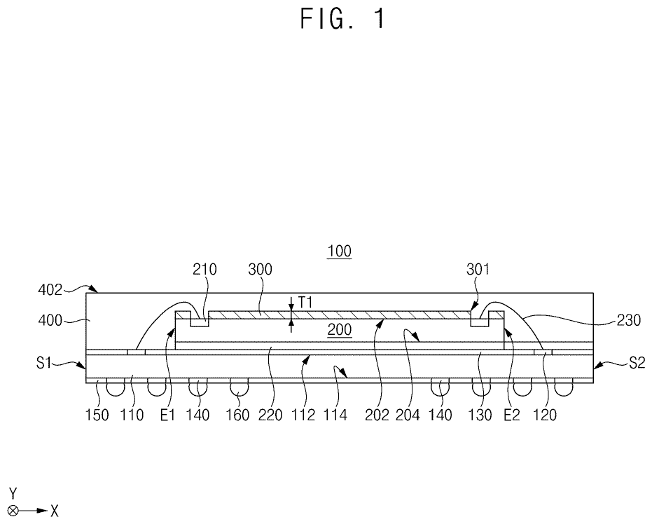

FIG. 1 is a cross-sectional view illustrating a semiconductor package in accordance with an example embodiment.

Referring to FIG. 1, a semiconductor package 100 may include a package substrate 110, a semiconductor chip 200, a stress control layer 300, and a sealing member 400. In addition, the semiconductor package 100 may further include external connection members 160.

In example embodiments, the package substrate 110 may be a substrate having an upper surface 112 and a lower surface 114 opposite to the upper surface 112. For example, the package substrate 110 may include a printed circuit board PCB, a flexible substrate, a tape substrate, etc. The printed circuit board may be a multilayer circuit board having vias and various circuits therein. The package substrate 110 may include internal wirings as channels for electrical connection with the semiconductor chip 200.

The package substrate 110 may include a first side portion S1 and a second side portion S2 extending in a direction parallel to a second direction (Y direction) and facing each other, and a third side portion S3 and a fourth side portion S4 extending in a direction parallel to a first direction (X direction) perpendicular to the second direction and facing each other.

The package substrate 110 may have a chip mounting region in a central region thereof. The chip mounting region may be a region on which the semiconductor chip 200 is mounted. The chip mounting region may have a rectangular shape.

The package substrate 110 may include substrate pads 120 that are arranged along the sides S1, S2 of the package substrate 110. The substrate pads 120 may be respectively connected to the wirings. The wirings may extend from the upper surface 112 or within the package substrate 110. For example, at least a portion of the wiring may be used as the substrate pad for a landing pad.

Although only a few substrate pads are illustrated in the figures, it will be understood that the number, shape and/or arrangement of the substrate pads are provided by way of example and that the present inventive concepts are not limited thereto.

A first insulating layer 130 may be formed on the upper surface 112 of the package substrate 110 and may expose the substrate pads 120. The first insulating layer 130 may cover the entire area of the upper surface 112 of the package substrate 110 except for the substrate pads 120. For example, the first insulating layer may include a solder resist.

In some example embodiments, the semiconductor chip 200 may be mounted on the chip mounting region of the package substrate 110. The semiconductor chip 200 may be mounted on the package substrate 110 by a wire bonding method. The semiconductor chip 200 may be arranged such that a backside surface 204, which is opposite to a front surface (e.g., an active surface) 202 on which chip pads 210 are formed faces the package substrate 110.

The semiconductor chip 200 may have a rectangular shape with four sides when viewed in a plan view. The semiconductor chip 200 may include a first side E1 and a second side E2 that extend in a direction parallel to the first direction (X direction) and face each other, and a third side and a fourth side that extend in a direction parallel to the second direction (Y direction) and face each other. The chip pads 210 may be arranged on the front surface 202 of the semiconductor chip 200 to be spaced apart from each other along the first and second sides E1, E2 that face each other.

The semiconductor chip 200 may be attached to the package substrate 110 by an adhesive film 220. The chip pads 210 of the semiconductor chip 200 may be electrically connected to the substrate pads 120 of the package substrate 110 by bonding wires 230 as conductive connection members.

In some example embodiments, the stress control layer 300 may be provided on the first surface 202 of the semiconductor chip 200. The stress control layer 300 may include a material having a residual stress in a compressive direction at room temperature after undergoing a thermal history during the manufacture of the semiconductor package. The stress control layer 300 may include a ceramic material. For example, the stress control layer 300 may include alumina (Al₂O₃), zirconia (ZrO₂), aluminum nitride (AlN), etc. The stress control layer 300 may have a thickness T1 of about 5 μm to about 20 μm.

The semiconductor chip 200 may have a first thermal expansion coefficient, and the stress control layer 300 may have a second thermal expansion coefficient greater than the first thermal expansion coefficient of the semiconductor chip 200 so as to have a residual stress in a compressive direction. For example, the first thermal expansion coefficient of the semiconductor chip 200 may be about 2.6×10⁻⁶/° C. The second thermal expansion coefficient of the stress control layer 300 may be within a range of about 4.0×10⁻⁶/° C. to about 20×10⁻⁶/°C. The thermal expansion coefficient of the stress control layer 300 including alumina (Al₂O₃) may be about 7.5×10⁻⁶/° C. The thermal expansion coefficient of the stress control layer 300 including zirconia (ZrO₂) may be about 10.5×10⁻⁶/° C. The thermal expansion coefficient of the stress control layer 300 including aluminum nitride (AlN) may be about 4.5×10⁻⁶/° C.

The stress control layer 300 may be formed on the entire area of the first surface 202 of the semiconductor chip 200. The stress control layer 300 may have openings 301 that expose the chip pads 210 of the semiconductor chip 200, respectively. In some example embodiments, the stress control layer 300 may be formed on a portion of the first surface 202 of the semiconductor chip 200. For example, the stress control layer 300 may be formed in a central region of the first surface 202 of the semiconductor chip 200.

In some example embodiments, the sealing member 400 may be provided on the upper surface 112 of the package substrate 110 to cover the semiconductor chip 200, the stress control layer 300 and the bonding wires 230. The sealing member may include a thermosetting resin, for example, an epoxy mold compound (EMC).

The sealing member 400 may have a third thermal expansion coefficient. The second thermal expansion coefficient of the stress control layer 300 may be greater than the third thermal expansion coefficient of the sealing member 400. For example, the third thermal expansion coefficient of the sealing member 400 may be in a range of about 2×10⁻⁶/° C. to about 12×10⁻⁶/° C.

In some example embodiments, outer connection pads 140 for providing an electric signal may be formed on the lower surface 114 of the package substrate 110. The outer connection pads 140 may be exposed by a second insulation layer 150. The second insulation layer may include a silicon oxide layer, a silicon nitride layer, or a silicon oxynitride layer. The external connection members 160 for electrical connection with an external device may be arranged on the outer connection pads 140 of the package substrate 110, respectively. For example, the external connection member 160 may be a solder ball. The semiconductor package 10 may be mounted on a module substrate (not illustrated) via the solder balls to constitute a memory module.

As mentioned above, the semiconductor package 10 may include the package substrate 110, the semiconductor chip 200 disposed on the package substrate 110 and having the first thermal expansion coefficient, the stress control layer 300 coated on the first surface 202 of the semiconductor chip 200 and having the second thermal expansion coefficient greater than the first thermal expansion coefficient so as to have a residual stress in a compressive direction, and the sealing member 400 covering the semiconductor chip 200 and the stress control layer 300 on the package substrate 110.

After manufacturing the semiconductor package 100, a 3-point bending test may be performed on the semiconductor package 100 to measure the mechanical properties of the semiconductor package 100. In the 3-point bending test, bending deformation (upward convexity) may occur in the semiconductor package 100. A tensile stress may occur in the semiconductor chip 200 due to the bending deformation of the semiconductor package 100. Because the stress control layer 300 has the residual stress in the compressive direction at room temperature, the stress control layer 300 may relieve or alleviate the tensile stress applied to the semiconductor chip 200.

Accordingly, the strength of the semiconductor package 100 in the bending test may be increased and cracks may be reduced or prevented from occurring in the sealing member 400 on which a marking pattern is formed.

Hereinafter, a method of manufacturing the semiconductor package of FIG. 1 will be described.

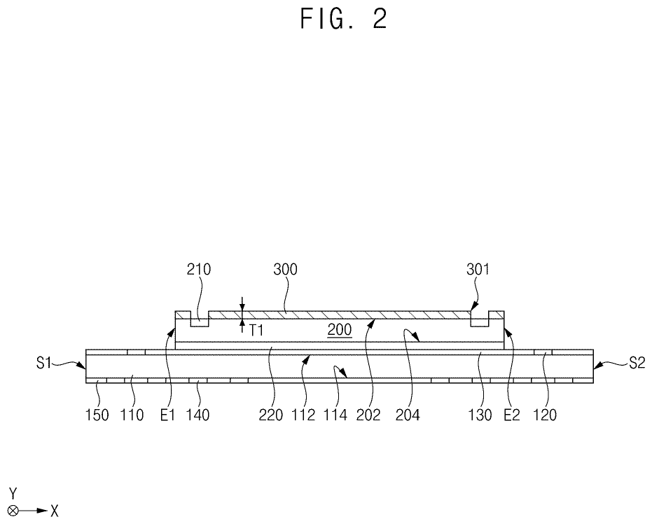

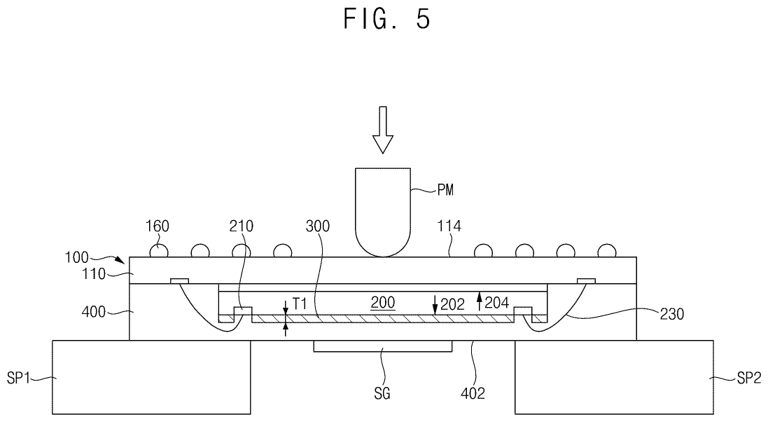

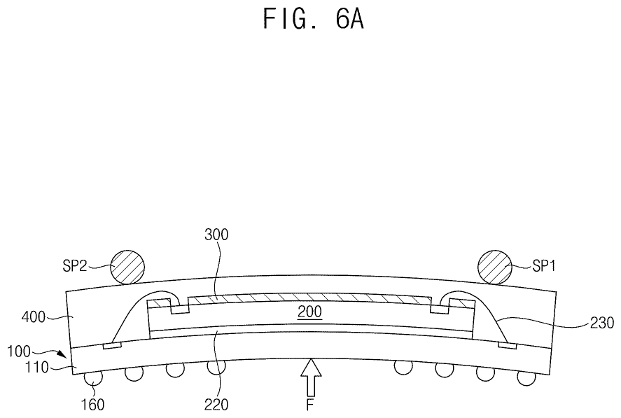

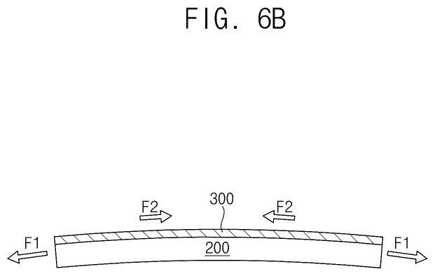

FIGS. 2 to 5 are views illustrating a method for manufacturing a semiconductor package in accordance with an example embodiment. FIG. 6A is a cross-sectional view illustrating a bending deformation of the semiconductor package in 3-point bending test of FIG. 5, and FIG. 6B is a cross-sectional view illustrated stresses applied to a semiconductor chip of the semiconductor package of FIG. 6A.

Referring to FIG. 2, at least one semiconductor chip 200 may be placed on a package substrate 110.

In some example embodiments, the package substrate 110 may be a substrate having an upper surface 112 and a lower surface 114 opposite to the upper surface 112. For example, the package substrate 110 may be a printed circuit board (PCB). The printed circuit board may be a multilayer circuit board having vias and various circuits therein. The package substrate 110 may include internal wirings of channels for electrical connection with the semiconductor chip.

The package substrate 110 may include a first side portion S1 and a second side portion S2 extending in a direction parallel to a second direction (Y direction) and facing each other, and a third side portion and a fourth side portion extending in a direction parallel to a first direction (X direction) perpendicular to the second direction and facing each other.

The package substrate 110 may have a chip mounting region in a central region thereof. As will be described below, the chip mounting region may be an area in which the semiconductor chip is mounted. The chip mounting region may have a rectangular shape.

The package substrate 110 may include substrate pads 120 that are arranged along the sides S1, S2 of the package substrate 110. The substrate pads 120 may be respectively connected to the wirings. The wirings may extend from the upper surface 112 or within the package substrate 110. For example, at least a portion of the wiring may be used as the substrate pad for a landing pad.

A first insulating layer 130 may be formed on the upper surface 112 of the package substrate 110 to expose the substrate pads 120. The first insulating layer 130 may cover the entire area of the upper surface 112 of the package substrate 110 except for the substrate pads 120. For example, the first insulating layer may include a solder resist.

Then, the semiconductor chip 200 may be placed on the chip mounting region of the package substrate 110. The semiconductor chip 200 may be attached to the package substrate 110 using an adhesive film 220.

In some example embodiments, the semiconductor chip 200 may have a first surface (front surface) 202 on which chip pads 210 are formed and a second surface (backside surface) 204 opposite to the first surface 202. The semiconductor chip 200 may be arranged such that the backside surface 204 opposite to the front surface (e.g., an active surface) 202 on which the chip pads 210 are formed, faces the package substrate 110. The semiconductor chip 200 may have a rectangular shape with four sides when viewed in a plan view. The chip pads 210 may be arranged on the front surface 202 of the semiconductor chip 200 to be spaced apart from each other along first and second sides E1, E2 facing each other.

For example, a thickness of the semiconductor chip 200 may be within a range of about 40 μm to about 150 μm. A thickness of the adhesive film 220 may be within a range of about 5 μm to about 20 μm.

In some example embodiments, a stress control layer 300 may be formed on the first surface 202 of the semiconductor chip 200. The stress control layer 300 may include a material having a residual stress in a compressive direction at room temperature after undergoing a thermal history during the manufacture of the semiconductor package. The stress control layer 300 may include a ceramic material. For example, the stress control layer 300 may include alumina (Al₂O₃), zirconia (ZrO₂), aluminum nitride (AlN), etc. The stress control layer may have a thickness T1 of about 5 μm to about 20 μm.

The semiconductor chip 200 may have a first thermal expansion coefficient, and the stress control layer 300 may have a second thermal expansion coefficient greater than the first thermal expansion coefficient of the semiconductor chip 200 so as to have a residual stress in a compressive direction. For example, the first thermal expansion coefficient of the semiconductor chip 200 may be about 2.6×10⁻⁶/° C. The second thermal expansion coefficient of the stress control layer 300 may be within a range of about 4.0×10⁻⁶/° C. to about 20×10⁻⁶/° C. The thermal expansion coefficient of the stress control layer 300 including alumina (Al₂O₃) may be about 7.5×10⁻⁶/° C. The thermal expansion coefficient of the stress control layer 300 including zirconia (ZrO2) may be about 10.5×10⁻⁶/° C. The thermal expansion coefficient of the stress control layer 300 including aluminum nitride (AlN) may be about 4.5×10⁻⁶/° C.

The stress control layer 300 may be formed by a deposition process such as a chemical vapor deposition (CVD) process, a spin coating process, or the like. After the stress control layer is coated on the entire surface of a silicon wafer in which the semiconductor chips are formed, the wafer may be cut by a sawing process to form individualized semiconductor chips, and then the individualized semiconductor chips may be attached to the upper surface 112 of the package substrate 110 using the adhesive film 220 by a die attach process.

In some example embodiments, the stress control layer 300 may be formed after the semiconductor chip is placed on the package substrate 110. In this case, after a mask is formed on the package substrate 110 to expose the first surface of the semiconductor chip, the stress control layer may be formed on the exposed first surface of the semiconductor chip.

The stress control layer 300 may be formed on the entire area of the first surface 202 of the semiconductor chip 200. The stress control layer 300 may have openings 301 that expose the chip pads 210 of the semiconductor chip 200, respectively. In some example embodiments, the stress control layer 300 may be formed on a portion of the first surface 202 of the semiconductor chip 200. For example, the stress control layer 300 may be formed in a central region on the first surface 202 of the semiconductor chip 200.

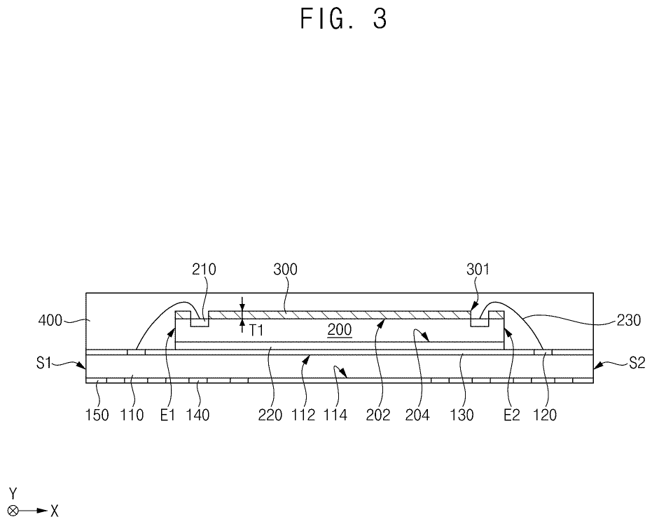

Referring to FIG. 3, the semiconductor chip 200 may be mounted on the package substrate 110 by a wire bonding method, and a sealing member 400 may be formed on the package substrate 110 to cover the semiconductor chip 200 and the stress control layer 300.

In some example embodiments, after the semiconductor chip 200 is attached on the upper surface 112 of the package substrate 110 using the adhesive film 220, a wire bonding process may be performed to connect the chip pads 210 of the semiconductor chip 200 to the substrate pads 120 on the upper surface 112 of the package substrate 110. The chip pads 210 of the semiconductor chip 200 may be connected to the substrate pads 120 by bonding wires 230 as conductive connecting members.

The sealing member 400 may be formed by a compression molding process or a transfer molding process. The sealing member 400 may entirely cover the stress control layer 300 on the semiconductor chip 200. The sealing member may include a thermosetting resin, for example, epoxy mold compound (EMC).

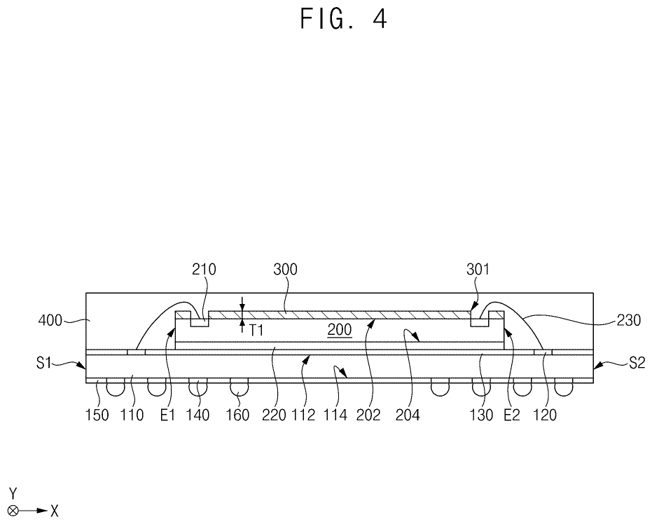

Referring to FIG. 4, external connection members 160 may be disposed on outer connection pads 140 on the lower surface 114 of the package substrate 110 to complete the semiconductor package.

For example, the external connection members may include solder balls. The external connection members 160 may be formed on the outer connection pads 140 of the lower surface 114 of the package substrate 110 by a solder ball attach process.

Referring to FIGS. 5 to 6B, a bending test may be performed on the completed semiconductor package 100 to measure mechanical properties of the semiconductor package 100. A 3-point bending test may be performed to measure mechanical properties of the semiconductor package 100, such as flexural modulus, flexural strength, and/or flexural yield strength.

As illustrated in FIG. 5, in an example embodiment, the semiconductor package 100 as a specimen may be placed on two first and second supports SP1, SP2, and a single upper pressurizing member PM placed between the first and second supports SP1, SP2 may be lowered to apply a load to the semiconductor package 100. At this time, the sealing member 400 of the semiconductor package 100 may be placed on the first and second supports SP1, SP2, and the upper pressurizing member PM may press the lower surface 114 of the package substrate 110. Accordingly, bending deformation may occur in the semiconductor package 100, and the mechanical properties such as flexural modulus, flexural strength, and/or flexural yield strength of the semiconductor package 100 may be measured through a strain gauge SG that is attached to an upper surface 402 of the sealing member 400.

As illustrated in FIGS. 6A and 6B, when a load F is applied to the semiconductor package 100 by the upper pressurizing member PM, the semiconductor package 100 may be bent (convex upward). The bending of the semiconductor package 100 may cause a tensile stress F1 to be generated in the semiconductor chip 200. Because the stress control layer 300 has a residual stress F2 in a compressive direction at room temperature, the tensile stress F1 applied to the semiconductor chip 200 may be offset or compensated for by the residual stress F2 in the compressive direction of the stress control layer 300, thereby reducing the tensile stress applied to the semiconductor chip 200. Accordingly, the strength of the semiconductor package 100 in the bending test may be increased, and cracks may be reduced or prevented from occurring in the sealing member 400 on which a marking pattern is formed.

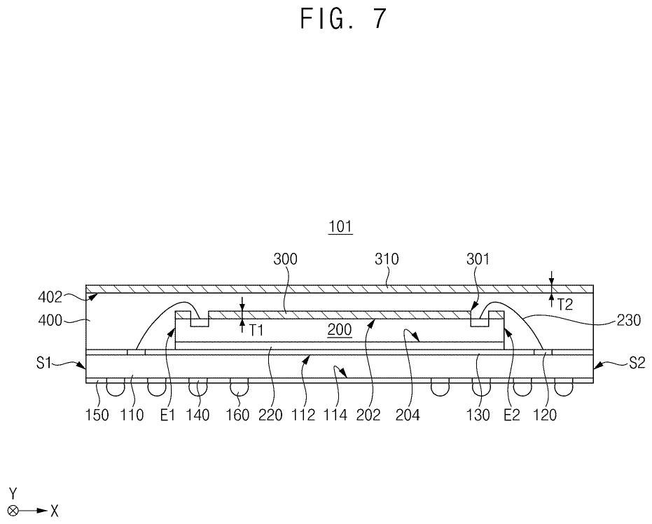

FIG. 7 is a cross-sectional view illustrating a semiconductor package in accordance with an example embodiment. The semiconductor package may be the same as or substantially similar to the semiconductor package described with reference to FIG. 1 except for an additional second stress control layer. Thus, same reference numerals will be used to refer to the same or like elements and any further repetitive explanation concerning the above elements will be omitted.

Referring to FIG. 7, a semiconductor package 101 may include a package substrate 110, a semiconductor chip 200, a first stress control layer 300, a sealing member 400, and a second stress control layer 310.

In example embodiments, the first stress control layer 300 may be coated on a first surface 202 of the semiconductor chip 200, and the second stress control layer 310 may be coated on an upper surface 402 of the sealing member 400. The second stress control layer 310 may be formed on the entire area of the upper surface 402 of the sealing member 400. In some example embodiments, the second stress control layer 310 may be formed on a portion of the upper surface 402 of the sealing member 400. For example, the second stress control layer 310 may be formed to overlap the semiconductor chip 200 in a central region on the first surface 202 of the semiconductor chip 200.

The first and second stress control layers 300, 310 may include a material having a residual stress in a compressive direction at room temperature after undergoing a thermal history during the manufacture of the semiconductor package. The first and second stress control layers 300, 310 may include a ceramic material. For example, the first and second stress control layers 300, 310 may include alumina (Al₂O₃), zirconia (ZrO₂), aluminum nitride (AlN), etc. The first stress control layer 300 may have a thickness T1 of about 5 μm to about 20 μm, and the second stress control layer 310 may have a thickness T2 of about 5 μm to about 20 μm.

The semiconductor chip 200 may have a first thermal expansion coefficient, the first stress control layer 300 may have a second thermal expansion coefficient greater than the first thermal expansion coefficient, and the second stress control layer 310 may have a third thermal expansion coefficient greater than the first thermal expansion coefficient. For example, the first thermal expansion coefficient may be about 2.6×10⁻⁶/° C. The second thermal expansion coefficient and the third thermal expansion coefficient may be within a range of about 4.0×10⁻⁶/° C. to about 20×10⁻⁶° C.

The thicknesses, thermal expansion coefficients, etc. of the first and second stress control layers may be determined in consideration of the tensile stress applied to the semiconductor chip in a bending test, the bending strength of the semiconductor chip, etc. In addition, the semiconductor package 101 may include only the second stress control layer 310 and the first stress control layer 300 may be omitted.

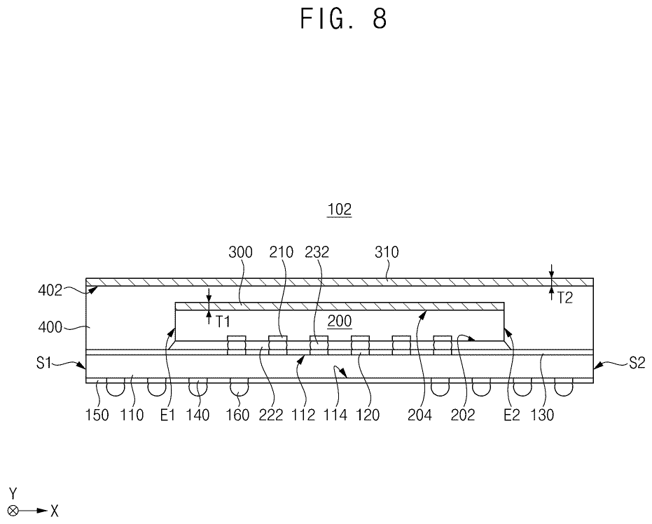

FIG. 8 is a cross-sectional view illustrating a semiconductor package in accordance with an example embodiment. The semiconductor package may be the same as or substantially similar to the semiconductor package described with reference to FIG. 7 except for a mounting method of a semiconductor chip. Thus, same reference numerals will be used to refer to the same or like elements and any further repetitive explanation concerning the above elements will be omitted.

Referring to FIG. 8, a semiconductor package 102 may include a package substrate 110, a semiconductor chip 200, a first stress control layer 300, a sealing member 400, and a second stress control layer 310.

In some example embodiments, the semiconductor chip 200 may be mounted on the package substrate 110 by a flip chip bonding method. The semiconductor chip 200 may be mounted on the package substrate 110 via conductive bumps 232 as conductive connecting members. The semiconductor chip 200 may be arranged such that a front surface (e.g., an active surface) 202 on which chip pads 210 are formed, faces the package substrate 110.

The chip pads 210 may be arranged in an array form on the entire area of the front surface 202 of the semiconductor chip 200. The chip pads 210 of the semiconductor chip 200 may be electrically connected to substrate pads 120 of the package substrate 110 by the conductive bumps 232, for example, solder bumps.

In addition, an underfill member 222 may be interposed between the semiconductor chip 200 and the package substrate 110. For example, the underfill member may include an epoxy material to reinforce a gap between the semiconductor chip 200 and the package substrate 110.

In example embodiments, the first stress control layer 300 may be provided on the backside surface 204 (e.g., an inactive surface) opposite to the front surface 202 of the semiconductor chip 200. The sealing member 400 may cover the first stress control layer 300. The second stress control layer 310 may be coated on an upper surface 402 of the sealing member 400.

The first and second stress control layers 300, 310 may include a material having a residual stress in a compressive direction at room temperature. The first and second stress control layers 300, 310 may include a ceramic material. For example, the first and second stress control layers 300, 310 may include alumina (Al₂O₃), zirconia (ZrO₂), aluminum nitride (AlN), etc. The first and second stress control layers 300, 310 may have a thickness of about 5 μm to about 20 μm.

The semiconductor chip 200 may have a first thermal expansion coefficient, the first stress control layer 300 may have a second thermal expansion coefficient greater than the first thermal expansion coefficient, and the second stress control layer 310 may have a third thermal expansion coefficient greater than the first thermal expansion coefficient. For example, the first thermal expansion coefficient may be about 2.6×10⁻⁶/° C. The second thermal expansion coefficient and the third thermal expansion coefficient may be within a range of about 4.0×10⁻⁶/° C. to about 20×10⁻⁶° C.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of some example embodiments and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the spirit and scope of the claims.

What is claimed is:

1. A semiconductor package, comprising:
a package substrate;
a semiconductor chip on an upper surface of the package substrate, the semiconductor chip having a first surface facing the package substrate and a second surface opposite to the first surface, the semiconductor chip having a first thermal expansion coefficient;
a first stress control layer on the second surface of the semiconductor chip, the first stress control layer having a second thermal expansion coefficient greater than the first thermal expansion coefficient; and
a sealing member on the upper surface of the package substrate and covering the semiconductor chip and the first stress control layer.

2. The semiconductor package of claim 1, wherein the first stress control layer include a ceramic material.

3. The semiconductor package of claim 2, wherein the first stress control layer includes at least one of alumina (Al₂O₃), zirconia (ZrO₂), or aluminum nitride (AlN).

4. The semiconductor package of claim 1, wherein the first stress control layer has a thickness of 5 μm to 20 μm.

5. The semiconductor package of claim 1, wherein the second thermal expansion coefficient within a range of 4.0×10⁻⁶/° C. to 20×10⁻⁶/° C.

6. The semiconductor package of claim 1, wherein
the package substrate has a plurality of substrate pads on the upper surface thereof, and the semiconductor chip has a plurality of chip pads on the second surface thereof, and
the semiconductor package further comprises bonding wires electrically connecting the plurality of chip pads and the plurality of substrate pads.

7. The semiconductor package of claim 1, wherein
the package substrate has a plurality of substrate pads on the upper surface thereof, and the semiconductor chip has a plurality of chip pads on the first surface thereof, and
the semiconductor package further comprises conductive connecting members electrically connecting the plurality of chip pads and the plurality of substrate pads.

8. The semiconductor package of claim 1, further comprising:
a second stress control layer on an upper surface of the sealing member, the second stress control layer having a third thermal expansion coefficient greater than the first thermal expansion coefficient.

9. The semiconductor package of claim 8, wherein the second stress control layer includes at least one of alumina (Al₂O₃), zirconia (ZrO₂), or aluminum nitride (AlN).

10. The semiconductor package of claim 8, wherein the third thermal expansion coefficient is within a range of 4.0×10⁻⁶/° C. to 20×10⁻⁶/° C.

11. A semiconductor package, comprising:
a package substrate;
a semiconductor chip on an upper surface of the package substrate and having a first thermal expansion coefficient;
a sealing member on the upper surface of the package substrate and covering the semiconductor chip; and
a first stress control layer on an upper surface of the sealing member, the first stress control layer having a second thermal expansion coefficient greater than the first thermal expansion coefficient.

12. The semiconductor package of claim 11, wherein the first stress control layer includes a ceramic material.

13. The semiconductor package of claim 12, wherein the first stress control layer includes at least one of alumina (Al₂O₃), zirconia (ZrO₂), or aluminum nitride (AlN).

14. The semiconductor package of claim 11, wherein the first stress control layer has a thickness of 5 μm to 20 μm.

15. The semiconductor package of claim 11, wherein the second thermal expansion coefficient is within a range of 4.0×10⁻⁶/° C. to 20×10⁻⁶° C.

16. The semiconductor package of claim 11, wherein
the semiconductor chip has a first surface facing the package substrate and a second surface opposite to the first surface, and the semiconductor chip has a plurality of chip pads on the second surface thereof, and
the semiconductor package further comprises bonding wires electrically connecting the plurality of chip pads and a plurality of substrate pads of the package substrate.

17. The semiconductor package of claim 11, wherein
the semiconductor chip has a first surface facing the package substrate and a second surface opposite to the first surface, and the semiconductor chip has a plurality of chip pads on the first surface thereof, and
the semiconductor package further comprises conductive connecting members electrically connecting the plurality of chip pads and a plurality of substrate pads of the package substrate.

18. The semiconductor package of claim 11, wherein
the semiconductor chip has a first surface facing the package substrate and a second surface opposite to the first surface,
the semiconductor package further comprises a second stress control layer on the second surface of the semiconductor chip, the second stress control layer having a third thermal expansion coefficient greater than the first thermal expansion coefficient.

19. The semiconductor package of claim 18, wherein the second stress control layer includes at least one of alumina (Al₂O₃), zirconia (ZrO₂), or aluminum nitride (AlN).

20. A semiconductor package, comprising:
a package substrate;
a semiconductor chip on an upper surface of the package substrate, the semiconductor chip having a first surface facing the package substrate and a second surface opposite to the first surface, the semiconductor chip having a first thermal expansion coefficient;
a first stress control layer on the second surface of the semiconductor chip, the first stress control layer having a second thermal expansion coefficient greater than the first thermal expansion coefficient;
a sealing member on the upper surface of the package substrate and covering the semiconductor chip and the first stress control layer; and
a second stress control layer on an upper surface of the sealing member, the second stress control layer having a third thermal expansion coefficient greater than the first thermal expansion coefficient.
